(19) United States
(12) Patent Application Publication
(10) Pub. No.: US 2025/0365959 A1
(43) Pub. Date: Nov. 27, 2025

(54) MEMORY DEVICE AND METHOD OF MANUFACTURING THE MEMORY DEVICE

(71) Applicant: SK hynix Inc., Icheon-si Gyeonggi-do (KR)

(72) Inventors: Do Young KIM, Icheon-si Gyeonggi-do (KR); Eun Mee KWON, Icheon-si Gyeonggi-do (KR)

(73) Assignee: SK hynix Inc., Icheon-si Gyeonggi-do (KR)

(21) Appl. No.: 18/977,613

(22) Filed: Dec. 11, 2024

(30) Foreign Application Priority Data
May 21, 2024 (KR) 10-2024-0065593

(51) Int. Cl. H10B 43/27; H10B 43/35

(52) U.S. Cl. CPC H10B 43/27; H10B 43/35

(57) ABSTRACT

Provided herein is a memory device and a method of manufacturing the memory device. The memory device includes gate lines stacked to be spaced apart from each other, first blocking layers enclosed by the gate lines and stacked to be spaced apart from each other, charge trap layers enclosed by the first blocking layers and stacked to be spaced apart from each other, protruding patterns located between the first blocking layers and between the charge trap layers, a tunnel isolation layer enclosed by the charge trap layers and the protruding patterns, and a channel layer enclosed by the tunnel isolation layer.

### CROSS-REFERENCE TO RELATED APPLICATION

The present application claims priority under 35 U.S.C. § 119(a) to Korean patent application number 10-2024-0065593 filed on May 21, 2024, in the Korean Intellectual Property Office, the entire disclosure of which application is incorporated by reference herein.

### BACKGROUND

### 1. Technical Field

Various embodiments of the present disclosure generally relate to a memory device and a method of manufacturing the memory device, and more particularly, to a memory device including a three-dimensional structure and a method of manufacturing the memory device.

### 2. Related Art

A memory device may include a memory cell array in which data is stored, and a peripheral circuit configured to perform the program, read or erase operation of the memory cell array.

The memory cell array may include memory blocks, and the memory blocks may be formed in a two-dimensional (2D) structure or a three-dimensional (3D) structure.

The memory block formed in the 2D structure may include memory cells arranged along a substrate. The memory block formed in the 3D structure may include memory cells that are vertically stacked on the substrate. The memory cells of the memory block formed in the 3D structure may be programmed by trapping charges in a charge trap layer.

In a typical 3D structure memory device, the charge trap layer may extend in a vertical direction. Because different memory cells trap charges in different areas of the charge trap layer extending in the vertical direction, interference between memory cells that are vertically adjacent to each other may increase, and retention characteristics that should maintain the threshold voltage of the programmed memory cells may be deteriorated.

### SUMMARY

An embodiment of the present disclosure may provide for a memory device. The memory device may include gate lines stacked to be spaced apart from each other. First blocking layers may be enclosed by the gate lines and be stacked to be spaced apart from each other. Charge trap layers may be enclosed by the first blocking layers and be stacked to be spaced apart from each other. Protruding patterns may be located between the first blocking layers and between the charge trap layers. A tunnel isolation layer may be enclosed by the charge trap layers and the protruding patterns. A channel layer may be enclosed by the tunnel isolation layer.

An embodiment of the present disclosure may provide for a method of manufacturing a memory device. The method may include alternately stacking first material layers and sacrificial layers, forming an opening to expose surfaces of the first material layers and the sacrificial layers, selectively forming protrusions on the first material layers exposed through the opening, forming first blocking layers and charge trap layers on the sacrificial layers exposed between the protrusions, forming protruding patterns by removing a portion of the protrusions that protrude between the charge trap layers, forming a tunnel isolation layer along surfaces of the protruding patterns and the charge trap layers, and forming a channel layer along a surface of the tunnel isolation layer.

### BRIEF DESCRIPTION OF THE DRAWINGS

FIG. 1 is a diagram illustrating an embodiment of a memory device.

FIG. 2 is a diagram illustrating an embodiment of a memory block.

FIGS. 3A, 3B, and 3C are views illustrating a structure of a memory device according to first embodiments of the present disclosure.

FIGS. 4A, 4B, 4C, 4D, 4E, 4F, 4G, 4H, 4I, 4J, 4K, 4L, 4M, 4N, and 4O are views illustrating a method of manufacturing a memory device according to first embodiments of the present disclosure.

FIGS. 5A and 5B are views illustrating a structure of a memory device according to second embodiments of the present disclosure.

FIG. 6 is a diagram illustrating an embodiment of a Solid State Drive (SSD) system to which a memory device of the present disclosure is applied.

FIG. 7 is a diagram illustrating an embodiment of a memory card system to which a memory device of the present disclosure is applied.

### DETAILED DESCRIPTION

Specific structural or functional descriptions, disclosed herein, are exemplified to describe embodiments according to the concept of the present disclosure. The embodiments according to the concept of the present disclosure should not be construed as being limited to embodiments described below, and may be modified in various forms and replaced with other equivalent embodiments.

Hereinafter, it will be understood that, although the terms “first” and “second” may be used herein to describe various elements, these elements should not be limited by these terms. The terms are used to distinguish one element from other elements. It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Terms such as “vertical,” “horizontal,” “over,” “side,” “lower,” “outer” and other terms implying relative spatial relationship or orientation are utilized only for the purpose of ease of description or reference to a drawing and are not otherwise limiting. The cross-hatching throughout the figures illustrates corresponding or similar areas between the figures rather than indicating the materials associated with the areas.

Various embodiments of the present disclosure are directed to a memory device and a method of manufacturing the memory device, which can improve retention characteristics of memory cells.

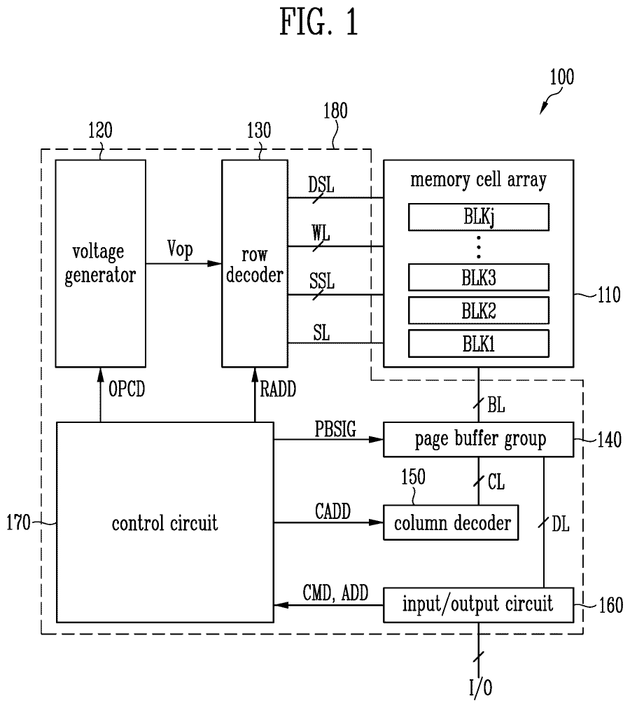

FIG. 1 is a diagram illustrating an embodiment of a memory device.

Referring to FIG. 1, a memory device 100 may include a memory cell array 110 and a peripheral circuit 180.

The memory cell array 110 may include first to j-th memory blocks BLK1 to BLKj. Each of the first to j-th memory blocks BLK1 to BLKj may include memory cells capable of storing data. Drain select lines DSL, word lines WL, source select lines SSL, and a source line SL may be coupled to each of the first to j-th memory blocks BLK1 to BLKj, and bit lines BL may be coupled in common to the first to j-th memory blocks BLK1 to BLKj.

Each of the first to j-th memory blocks BLK1 to BLKj may be formed to have a two-dimensional (2D) structure or a three-dimensional (3D) structure. Each memory block having a 2D structure may include memory cells arranged in parallel on a substrate. Each memory block having a 3D structure may include memory cells stacked on a substrate in a vertical direction. In the present embodiment, each memory block formed to have the 3D structure is disclosed as an embodiment.

According to a program scheme, each memory cell may store 1 bit of data or 2 or more bits of data. For example, a scheme for storing 1 bit of data in one memory cell is referred to as a single-level cell (SLC) scheme, and a scheme for storing 2 bits of data in one memory cell is referred to as a multi-level cell (MLC) scheme. A scheme for storing 3 bits of data in one memory cell is referred to as a triple-level cell (TLC) scheme, and a scheme for storing 4 bits of data in one memory cell is referred to as a quad-level cell (QLC) scheme. In addition, 5 or more bits of data may be stored in one memory cell.

The peripheral circuit 180 may perform a program operation of storing data in the memory cell array 110, a read operation of outputting data stored in the memory cell array 110, and an erase operation of erasing data stored in the memory cell array 110. For example, the peripheral circuit 180 may include a voltage generator 120, a row decoder 130, a page buffer group 140, a column decoder 150, an input/output circuit 160, and a control circuit 170.

The voltage generator 120 may generate various operating voltages Vop that are used for a program operation, a read operation, or an erase operation in response to an operation code OPCD. For example, the voltage generator 120 may generate program voltages, turn-on voltages, turn-off voltages, negative voltages, precharge voltages, verify voltages, read voltages, pass voltages, or erase voltages in response to the operation code OPCD. The operating voltages Vop generated by the voltage generator 120 may be applied to the drain select lines DSL, the word lines WL, the source select lines SSL, and the source line SL of a memory block selected through the row decoder 130.

The program voltages may be voltages that are applied to the selected word line among the word lines WL during a program operation, and may be used to increase the threshold voltages of memory cells coupled to the selected word line. The turn-on voltages may be applied to the drain select lines DSL or the source select lines SSL, and may be used to turn on drain select transistors or source select transistors. The turn-off voltages may be applied to the drain select lines DSL or the source select lines SSL, and may be used to turn off the drain select transistors or the source select transistors. For example, the turn-off voltages may be set to 0 V. The precharge voltages may be voltages higher than 0 V, and may be applied to the bit lines during a read operation. The verify voltages may be used during a verify operation of determining whether the threshold voltages of selected memory cells have increased to a target level. The verify voltages may be set to various levels according to the target level, and may be applied to the selected word line.

The read voltages may be applied to the selected word line during a read operation performed on the selected memory cells. For example, the read voltages may be set to various levels according to the program scheme for the selected memory cells. The pass voltages may be voltages that are applied to unselected word lines among the word lines WL during a program or read operation, and may be used to turn on memory cells coupled to the unselected word lines.

The erase voltages may be used during an erase operation of erasing the memory cells included in the selected memory block, and may be applied to the source line SL.

The row decoder 130 may transmit the operating voltages Vop to the drain select lines DSL, the word lines WL, the source select lines SSL, and the source line SL, which are coupled to a memory block selected according to a row address RADD. For example, the row decoder 130 may be coupled to the voltage generator 120 through global lines, and may be coupled to the first to j-th memory blocks BLK1 to BLKj through the drain select lines DSL, the word lines WL, the source select lines SSL, and the source line SL.

The page buffer group 140 may include page buffers (not illustrated) coupled to the first to j-th memory blocks BLK1 to BLKj, respectively. The page buffers (not illustrated) may be coupled to the first to j-th memory blocks BLK1 to BLKj, respectively, through the bit lines BL. During a read operation, the page buffers (not illustrated) may sense the currents or voltages of the bit lines varying with the threshold voltages of the selected memory cells in response to page buffer control signals PBSIG, and may store the sensed data.

The column decoder 150 may be configured such that data is transferred between the page buffer group 140 and the input/output circuit 160 in response to a column address CADD. For example, the column decoder 150 may be coupled to the page buffer group 140 through column lines CL, and may transmit enable signals through the column lines CL. The page buffers (not illustrated) included in the page buffer group 140 may receive or output data through data lines DL in response to the enable signals.

The input/output circuit 160 may receive or output a command CMD, an address ADD, or data through input/output lines I/O. For example, the input/output circuit 160 may transmit the command CMD and the address ADD, received from an external controller through the input/output lines I/O, to the control circuit 170, and may transmit the data, received from the external controller through the input/output lines I/O, to the page buffer group 140. Alternatively, the input/output circuit 160 may output data, received from the page buffer group 140, to the external controller through the input/output lines I/O.

The control circuit 170 may output the operation code OPCD, the row address RADD, the page buffer control signals PBSIG, and the column address CADD in response to the command CMD and the address ADD. For example, when the command CMD input to the control circuit 170 is a command corresponding to a program operation, the control circuit 170 may control the devices included in the peripheral circuit 180 so that the program operation is performed on a memory block selected by the address ADD. When the command CMD input to the control circuit 170 is a command corresponding to a read operation, the control circuit 170 may control the devices included in the peripheral circuit 180 so that the read operation is performed on a memory block selected by the address and read data is output. When the command CMD input to the control circuit 170 is a command corresponding to an erase operation, the control circuit 170 may control the devices included in the peripheral circuit 180 so that the erase operation is performed on a selected memory block.

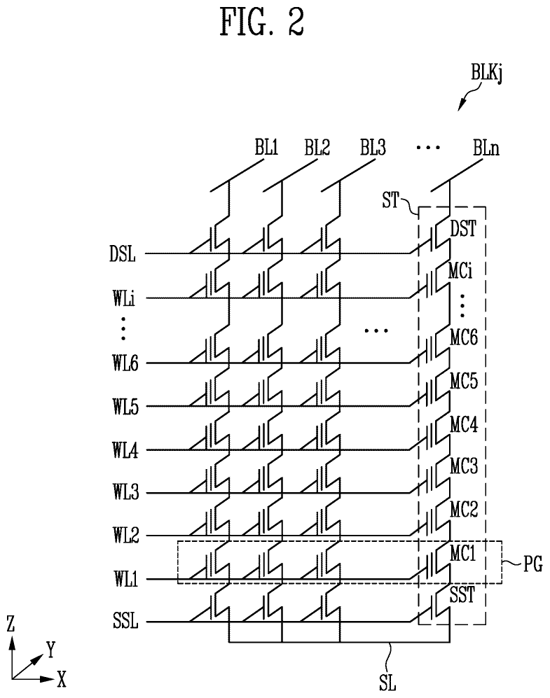

FIG. 2 is a diagram illustrating an embodiment of a memory block.

Because the first to j-th memory blocks BLK1 to BLKj illustrated in FIG. 1 may be configured in the same manner, the j-th memory block BLKj among the first to j-th memory blocks BLK1 to BLKj is illustrated as an example.

Referring to FIG. 2, the j-th memory block BLKj may include strings ST coupled between first to n-th bit lines BL1 to BLn (i.e., BL in FIG. 1) and a source line SL. Because the first to n-th bit lines BL1 to BLn extend along a Y direction and are arranged to be spaced apart from each other along an X direction, the strings ST extending along a Z direction may be arranged to be spaced apart from each other along the X and Y directions. In FIG. 2, the strings ST arranged in the X direction are illustrated.

When any one string ST among the strings ST coupled to the n-th bit line BLn is described by way of example, the string ST may include a source select transistor SST, first to i-th memory cells MC1 to MCi, and a drain select transistor DST. Because the j-th memory block BLKj illustrated in FIG. 2 schematically explains the connection configuration of the memory block, the numbers of source select transistors SST, first to i-th memory cells MC1 to MCi, and drain select transistors DST included in each of the strings ST may vary depending on the memory device.

Gates of source select transistors SST included in different strings ST may be coupled to a source select line SSL, gates of the first to i-th memory cells MC1 to MCi may be coupled to first to i-th word lines WL1 to WLi, and gates of drain select transistors DST may be coupled to a drain select line DSL.

Memory cells formed on the same layer among the first to i-th memory cells MC1 to MCi may be coupled to the same word line. For example, the first memory cells MC1 included in different strings ST may be coupled in common to the first word line WL1, and the i-th memory cells MCi included in different strings ST may be coupled in common to the i-th word line WLi. A group of memory cells included in different strings ST and coupled to the same word line may be a page (PG). The program and read operations may be performed on a page (PG) basis, and the erase operation may be performed on a memory block basis.

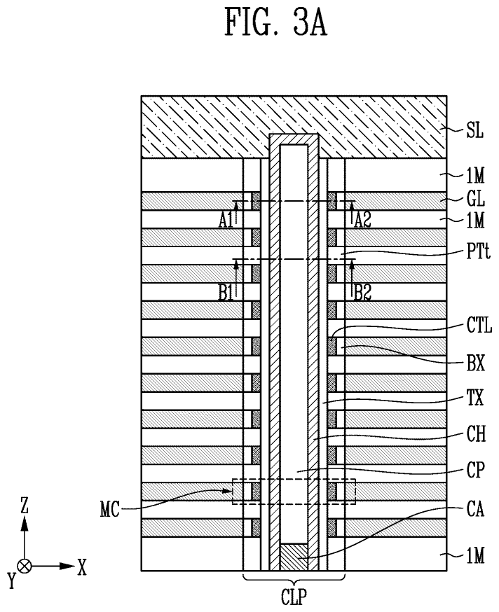

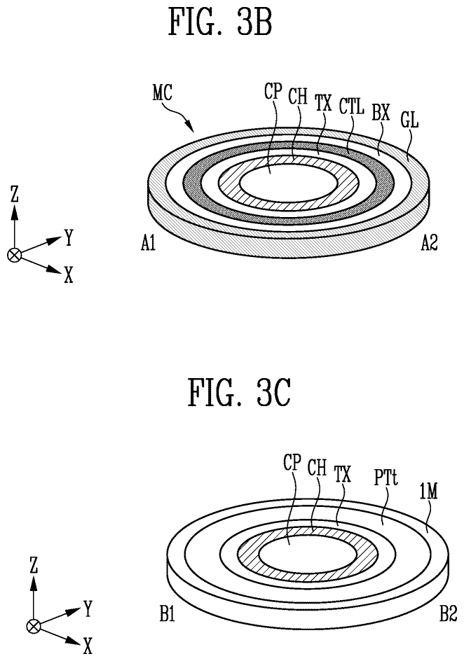

FIGS. 3A to 3C are views illustrating a structure of a memory device according to first embodiments of the present disclosure.

FIG. 3A shows a portion of a memory block included in the memory device, FIG. 3B shows the structure of a memory cell MC, and FIG. 3C shows a structure between memory cells MC.

Referring to FIGS. 3A to 3C, the memory block may include first material layers 1M and gate lines GL that are alternately stacked, and a cell plug CLP that penetrate the first material layers 1M and the gate lines GL in a vertical direction. The memory cells MC may be included in the cell plug CLP. The cell plug CLP may include protruding patterns PTt, blocking layers BX, charge trap layers CTL, tunnel isolation layers TX, channel layers CH, and a core pillar CP.

The memory cells MC may be stacked in a Z direction. Taking any one of the memory cells MC as an example, the memory cell MC may be enclosed by the gate line GL. The gate line GL may be formed of a conductive material. For instance, the gate line GL may be formed of a metal material such as tungsten (W), molybdenum (Mo), cobalt (Co), and nickel (Ni), or a semiconductor material such as silicon (Si) or polysilicon (Poly-Si).

The memory cell MC may have a circle or ellipse shape in an XY plane, but is not limited to the circle or ellipse shape. Referring to an A1-A2 plane, the memory cell MC may include the blocking layer BX, the charge trap layer CTL, the tunnel isolation layer TX, the channel layer CH, and the core pillar CP. The blocking layer BX may be located between the gate line GL and the charge trap layer CTL, and may be formed of an insulating material. For instance, the blocking layer BX may be formed of a silicon oxide layer. The charge trap layer CTL may be enclosed by the blocking layer BX. The charge trap layer CTL may be formed of a nitride material. For instance, the charge trap layer CTL may be formed of SiN or SiON. The tunnel isolation layer TX may be enclosed by the charge trap layer CTL. The tunnel isolation layer TX may be formed of an insulating material. For instance, the tunnel isolation layer TX may be formed of a silicon oxide material. The channel layer CH may be enclosed by the tunnel isolation layer TX. The channel layer CH may be formed of doped polysilicon or undoped polysilicon. The core pillar CP may be enclosed by the channel layer CH. The core pillar CP may be formed of an insulating material or a conductive material.

Referring to a B1-B2 plane between the memory cells MC, the charge trap layer CTL might not be located between the memory cells MC, but the protruding pattern PTt may be located therebetween. For instance, the first material layer 1M, the protruding pattern PTt, the tunnel isolation layer TX, the channel layer CH, and the core pillar CP may be located between the memory cells MC. The protruding pattern PTt may be located between the charge trap layers CTL of the memory cells MC. The protruding pattern PTt may be formed of an insulating material. For instance, the protruding pattern PTt may be formed of a silicon oxide layer.

In the structure of the memory device described above, in an embodiment, because the charge trap layers CTL included in the memory cells MC are electrically blocked by the protruding patterns PTt between the memory cells MC, retention characteristics, which are characteristics in which electrons trapped in the programmed memory cells are maintained, can be improved.

The method of manufacturing the memory device according to the first embodiments will be described as follows.

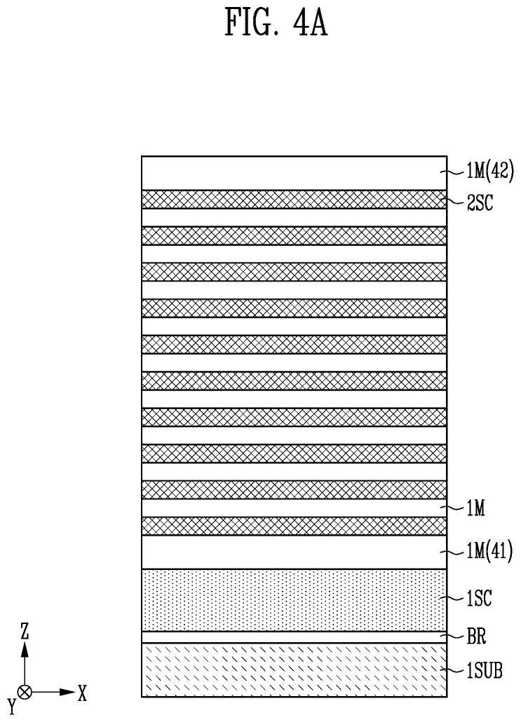

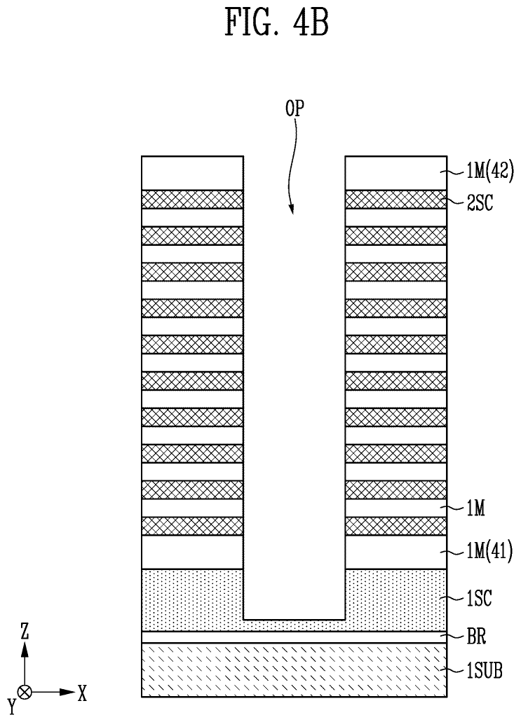

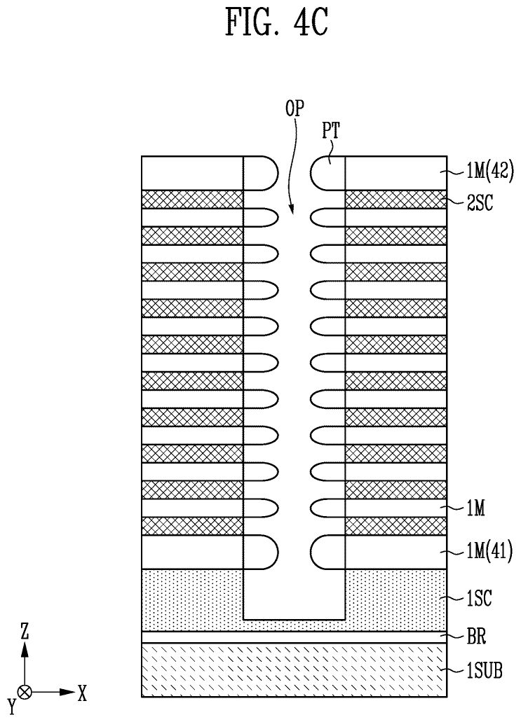

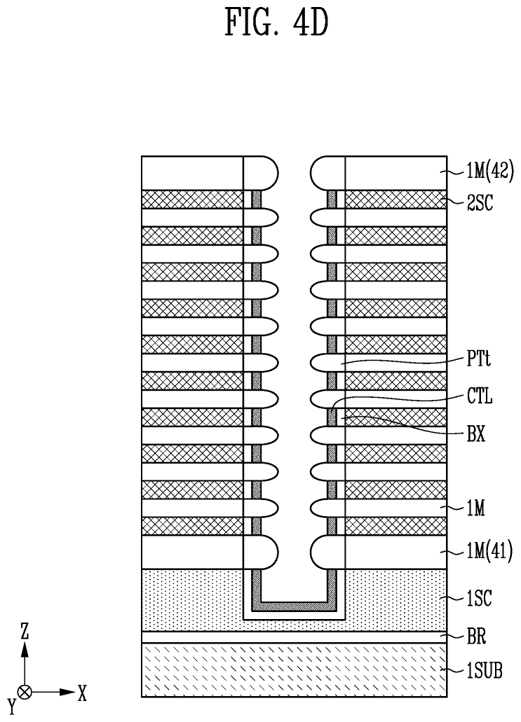

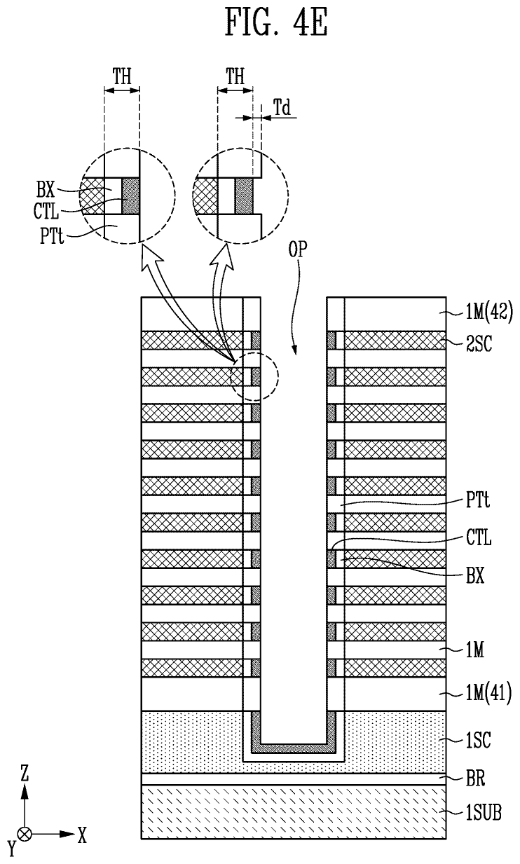

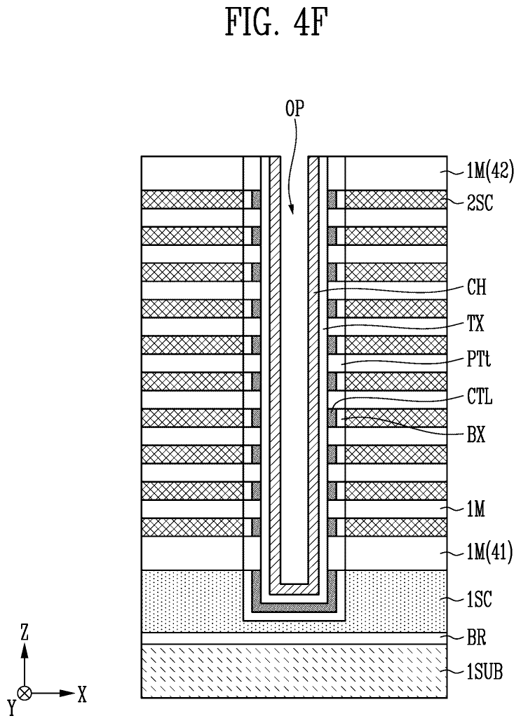

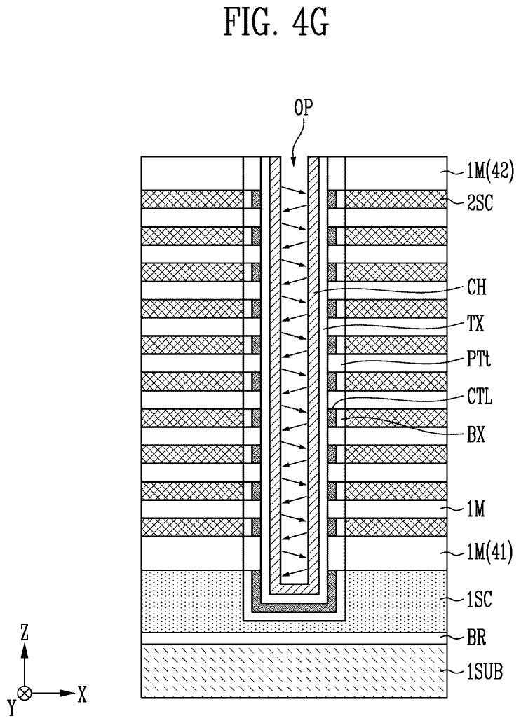

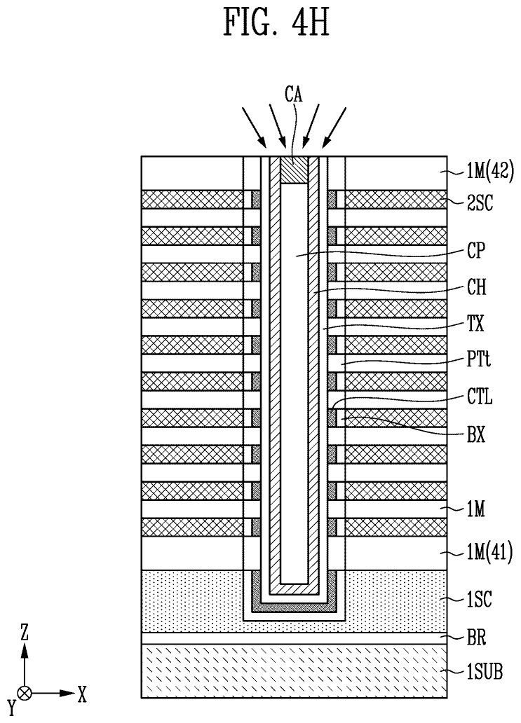

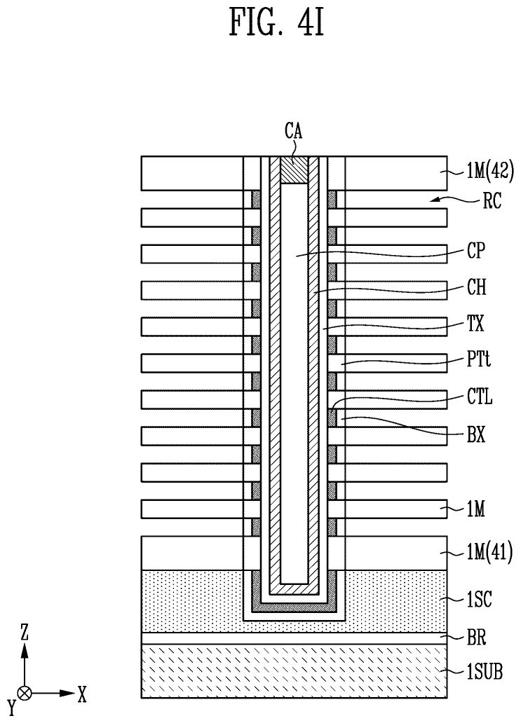

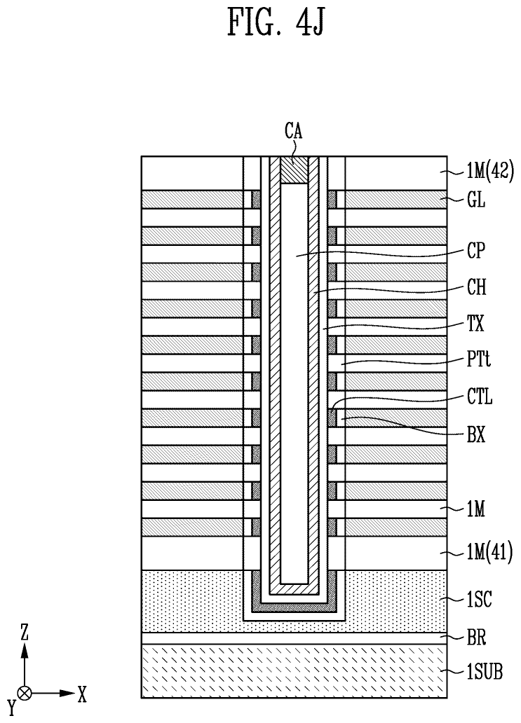

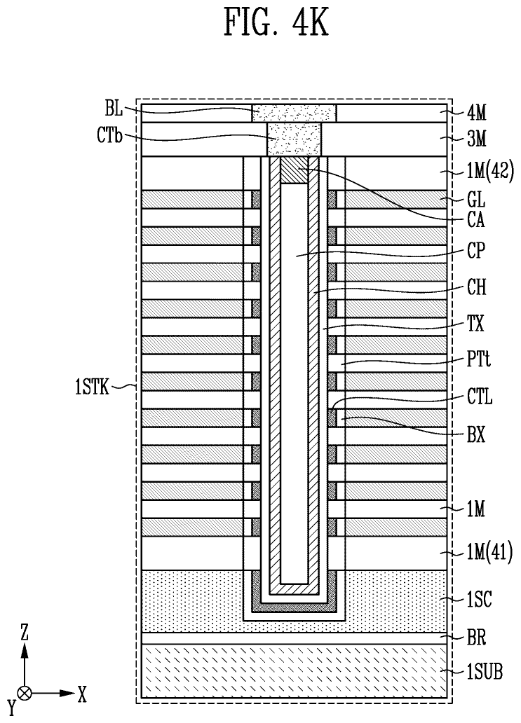

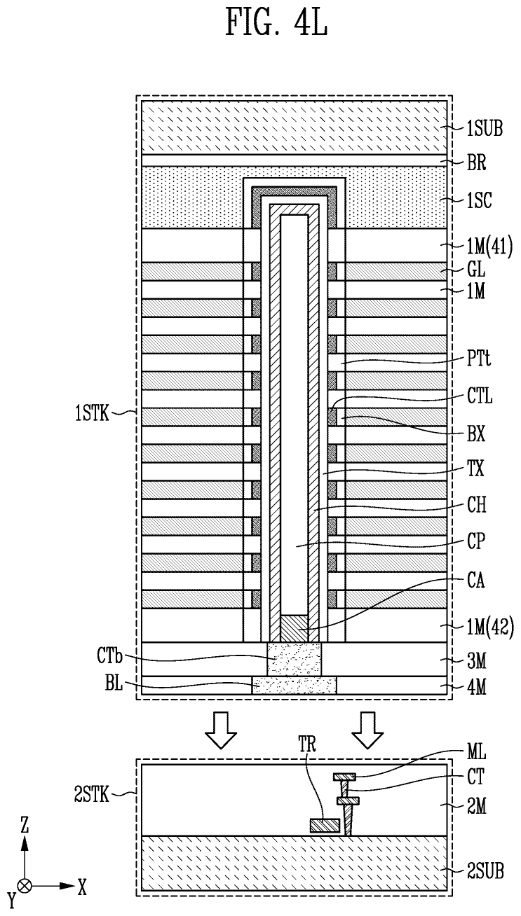

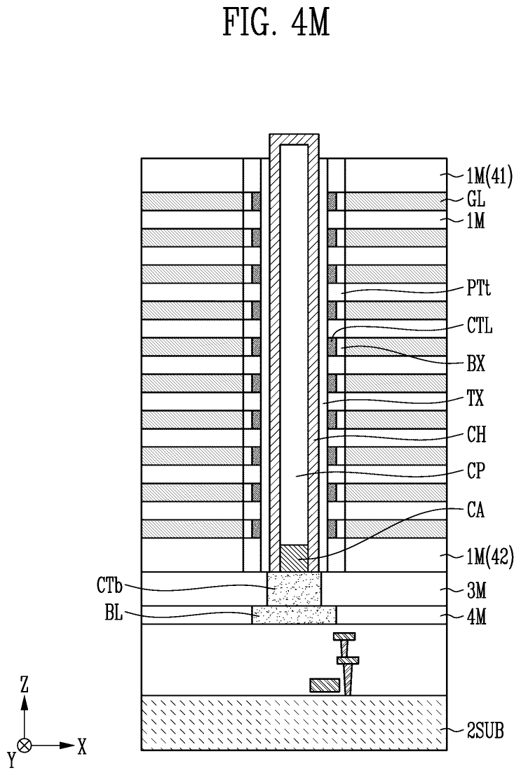

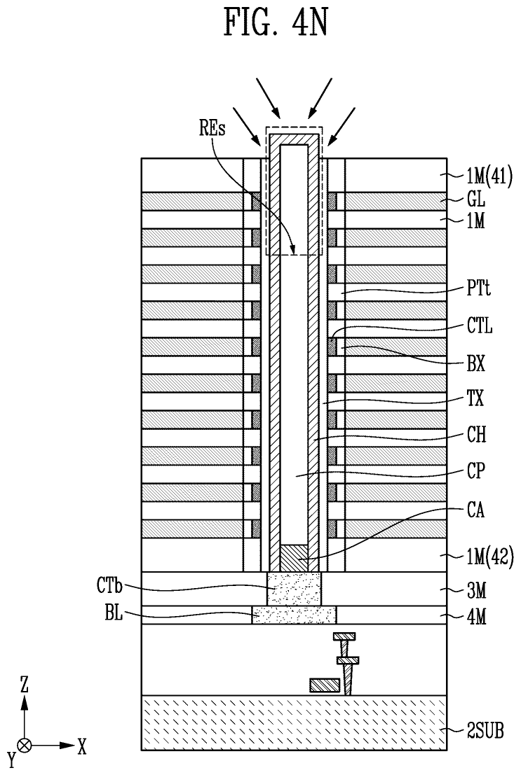

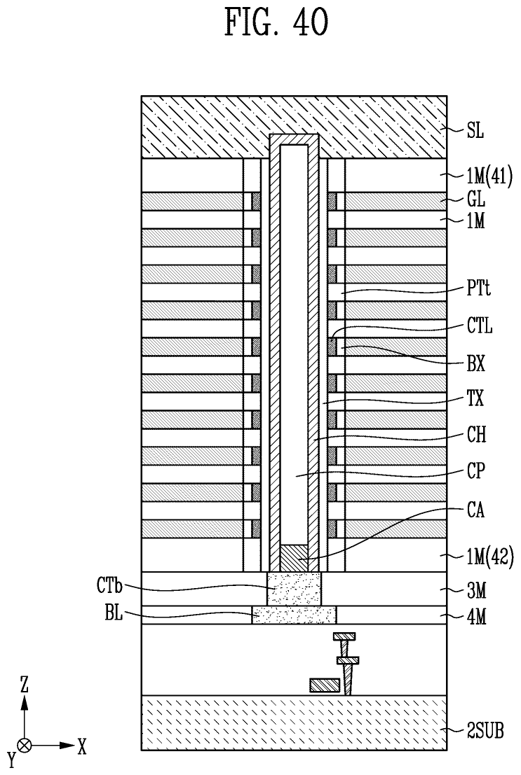

FIGS. 4A to 4O are views illustrating a method of manufacturing a memory device according to first embodiments of the present disclosure.

Referring to FIG. 4A, a barrier layer BR, a first sacrificial layer 1SC, first material layers 1M, and second sacrificial layers 2SC may be stacked on a lower structure. The lower structure may be a first substrate 1SUB. For instance, the first substrate 1SUB may be a silicon substrate. The barrier layer BR may be formed on the first substrate 1SUB. The barrier layer BR may be formed of an insulating material. For instance, the barrier layer BR may be formed of a silicon oxide layer. The first sacrificial layer 1SC may be formed on the barrier layer BR. For instance, the first sacrificial layer 1SC may be formed of polysilicon. The first material layers 1M and the second sacrificial layers 2SC may be alternately stacked on the first sacrificial layer 1SC. Among the first material layers 1M, the first material layer 41 located at the bottom and contacting the first sacrificial layer 1SC, and the first material layer 42 located at the top and having its upper surface exposed may be formed to have a thicker thickness (i.e., in the Z direction) than the remaining first material layers 1M. The first material layers 1M may be formed of an insulating material. For instance, the first material layers 1M may be formed of a silicon oxide layer. The second sacrificial layers 2SC may be formed of a material having an etch selectivity with the first material layers 1M. For instance, the second sacrificial layers 2SC may be formed of a nitride material. In an embodiment, first material layers 1M may be alternately stacked with sacrificial layers comprising of the second sacrificial layers 2SC.

Referring to FIG. 4B, an opening OP that penetrates the first material layers 1M and the second sacrificial layers 2SC and exposes a portion of the first sacrificial layer 1SC may be formed. For instance, the opening OP may be formed by performing an anisotropic dry etching process. The XY plane layout of the opening OP may have the shape of a circle, ellipse, or polygon, etc. Because the opening OP is vertically formed in the first substrate 1SUB, partial surfaces of the first material layers 1M and the second sacrificial layers 2SC may be exposed through the opening OP, and a portion of the surface of the first sacrificial layer 1SC may also be exposed.

Referring to FIG. 4C, protrusions PT may be selectively formed on surfaces of the first material layers 1M exposed through the opening OP. The protrusions PT may be formed of an insulating material. For instance, the protrusions PT may grow from the surfaces of the first material layers 1M through an oxidation process. Therefore, the protrusions PT may protrude from the first material layers 1M exposed through the opening OP toward the center of the opening OP. In an embodiment, the protrusions PT may protrude from the first material layers 1M exposed through the opening OP toward the center of the opening OP as shown in FIG. 4C. The oxidation process may be performed so that the protrusions PT formed in the same layer and facing each other do not contact each other.

Referring to FIG. 4D, blocking layers BX may be formed along the surfaces of the second sacrificial layers 2SC exposed between the protrusions PT. The blocking layers BX may be formed of an insulating material. For instance, the blocking layers BX may be formed of a silicon oxide layer. The blocking layers BX may be formed in-situ within the same chamber during the oxidation process for forming the protrusions PT described with reference to FIG. 4C. The blocking layers BX may be formed to have a thickness thinner than that of the protrusions PT. When the blocking layers BX are formed, the charge trap layers CTL may be formed in a portion enclosed by the blocking layers BX and the protrusions PT. For instance, the charge trap layers CTL may be formed of a nitride material. Because the blocking layers BX are formed between the protrusions PT and the charge trap layers CTL are formed on the surfaces of the blocking layers BX, the protrusions PT may be located between the charge trap layers CTL located in the vertical direction. As such, in an embodiment, because the protrusions PT are located between the charge trap layers CTL stacked in the Z direction and electrons are trapped in the charge trap layers CTL during the program operation, interference that may occur between the charge trap layers CTL adjacent to each other in the Z direction may be reduced. Because the charge trap layers CTL may remain on some surfaces of the protrusions PT when the charge trap layers CTL are formed between the protrusions PT, an etching process or a cleaning process may be performed to remove a portion of the charge trap layers CTL that may remain on the surfaces of the protrusions PT after the charge trap layers CTL are formed.

Referring to FIG. 4E, an etching process may be performed to remove a portion of the protrusions PT that protrude toward the center of the opening OP between the charge trap layers CTL. For instance, a portion of the protrusions PT may be removed by performing the anisotropic dry etching process. When a portion of the protrusions PT is removed, the protruding patterns PTt may remain between the charge trap layers CTL and the blocking layers BX. The etching process for removing a portion of the protrusions PT may be performed until the surfaces of the protruding patterns PTt are vertically aligned with the surfaces of the charge trap layers CTL. Thus, the combined thickness TH of each blocking layer BX and each charge trap layer CTL may be equal to the thickness TH of each of the protruding patterns PTt. In an embodiment, a sum of thicknesses comprising a first blocking layer and a charge trap layer (i.e., TH) located on the same layer among the first blocking layers (i.e., BX) and the charge trap layers (i.e., CTL) is substantially identical to a thickness of a protruding pattern (i.e., PTt) from among the protruding patterns. In an embodiment, the blocking layer BX and the charge trap layer CTL may extend in the X and Y plane, and a thickness TH may be measured in the X and Y plane as shown in FIG. 4E. In an embodiment the gate lines may be stacked in the Z direction as shown in FIG. 4E. Alternatively, the etching process may be stopped when the thickness of the protruding patterns PTt is thicker than that of the charge trap layers CTL by a certain thickness Td. Thus, the thickness of each of the protruding patterns PTt may be thicker than the combined thickness TH of each blocking layer BX and each charge trap layer CTL by a certain thickness difference Td. In an embodiment, a sum of thicknesses (i.e., TH) of a first blocking layer (i.e., BX) and a charge trap layer (i.e., CTL) located on the same layer among the first blocking layers and the charge trap layers is less than a thickness of a protruding pattern (i.e., PTt) from among the protruding patterns as shown in FIG. 4E.

Referring to FIG. 4F, the tunnel isolation layer TX may be formed along the surfaces of the charge trap layers CTL and the protruding patterns PTt exposed through the opening OP. The tunnel isolation layer TX may be formed of an insulating material. For example, the tunnel isolation layer TX may be formed of a silicon oxide layer. Subsequently, the channel layer CH may be formed along the surface of the tunnel isolation layer TX. The channel layer CH may be formed of doped polysilicon or undoped polysilicon.

Referring to FIG. 4G, a gas phase diffusion process, as indicated by the arrows, may be performed to implant impurities into the channel layer CH exposed through the opening OP. The gas phase diffusion process may be performed using N-type gas. For instance, a process of supplying gas containing phosphorus (P) into a chamber may be performed to uniformly implant phosphorus (P), which is an N-type impurity, into the channel layer CH. After the impurities are implanted into the channel layer CH, a heat treatment process may be performed to diffuse the N-type impurity into the channel layer CH. In an embodiment, when the N-type impurity is implanted into the channel layer CH, the conductivity of the channel layer CH may increase. This may, in an embodiment, increase the current amount of the channel layer CH during the program, read, or erase operation. In an embodiment, when the current amount in the channel layer CH increases, the reliability of a sensing operation performed depending on the current amount of the channel layer CH can be improved. As a result, in an embodiment, the threshold voltage distribution of the memory cells may become narrow.

Between the gas injection process and the heat treatment process, a step of additionally forming the channel layer along the surface of the channel layer CH may be further performed. When the thickness of the channel layer CH increases and the width of the opening OP decreases, the width of the opening OP may be increased by performing an isotropic etching process.

When the channel layer CH is formed of doped polysilicon, the gas injection process described with reference to FIG. 4G may be omitted.

Referring to FIG. 4H, a core pillar CP and a capping layer CA may be formed in a portion enclosed by the channel layer CH. For instance, after the core pillar CP is formed in a portion enclosed by the channel layer CH, the capping layer CA may be formed in a portion enclosed by the core pillar CP and the channel layer CH. The core pillar CP may be formed of an insulating material or a conductive material. The capping layer CA may be formed of a conductive material. After the capping layer CA is formed, an ion implantation process for implanting an impurity into a portion of the channel layer CH including the capping layer CA may be further performed. During the ion implantation process, phosphorus (P) or boron (B) may be used as an impurity, or a mixed impurity of phosphorus (P) or boron (B) may be used. The impurity may be implanted into the channel layer CH of a drain region where drain select transistors are located.

Referring to FIG. 4I, an etching process may be performed to remove the second sacrificial layers 2SC. The second sacrificial layers 2SC may be removed through a trench in a slit (not illustrated) area that separates memory blocks. When the second sacrificial layers 2SC are removed, recesses RC, which are empty spaces, may be formed between the first material layers 1M. For instance, the first material layers 1M and the blocking layers BX may be exposed through the recesses RC.

Referring to FIG. 4J, gate lines GL may be formed in the recesses RC. For instance, the gate lines GL may be formed of a conductive material. The gate lines GL may be formed of a metal material such as tungsten (W), molybdenum (Mo), cobalt (Co), and nickel (Ni), or a semiconductor material such as silicon (Si) or polysilicon (Poly-Si). The gate lines GL may contact the blocking layers BX and the first material layers 1M.

Referring to FIG. 4K, a bit line contact CTb contacting the channel layer CH and a bit line BL contacting the bit line contact CTb may be formed. For instance, a third material layer 3M may be formed on the capping layer CA and the first material layer 1M. The third material layer 3M may be formed of an insulating material. When the third material layer 3M is formed, an etching process for removing a portion of the third material layer 3M may be performed to expose the surfaces of the channel layer CH and the capping layer CA. The bit line contact CTb may be formed in an area where a portion of the third material layer 3M is removed. The bit line contact CTb may be formed of a conductive material. A fourth material layer 4M may be formed on the bit line contact CTb and the third material layer 3M. The fourth material layer 4M may be formed of an insulating material. When the fourth material layer 4M is formed, an etching process for removing a portion of the third material layer 3M may be performed to expose the surface of the bit line contact CTb. The bit line contact CTb may be formed in an area where a portion of the third material layer 3M is removed. The bit line contact CTb may be formed of a conductive material. Thus, a first structure 1STK including the bit line BL may be formed.

Referring to FIG. 4L, the first structure 1STK may be flipped, and the flipped first structure 1STK may contact a second structure 2STK. The second structure 2STK may include a peripheral circuit. For instance, the second structure 2STK may include a second substrate 2SUB, a second material layer 2M, a transistor TR, a contact CT, and a line ML. For instance, the second substrate 2SUB may be a silicon substrate. The second material layer 2M is an insulating material and may be formed on the second substrate 2SUB. The transistor TR, the contact CT, and the line ML are conductive materials and may be formed in the second material layer 2M. Because the transistor TR, the contact CT, and the line ML may have various layouts and structures depending on the peripheral circuit, these embodiments are not limited to a specific structure. Because the flipped first structure 1STK is located on the second structure 2STK, the first substrate 1SUB of the first structure 1STK may be located at the top.

Referring to FIG. 4M, an etching process may be performed to remove the first substrate 1SUB, the barrier layer BR, the first sacrificial layer 1SC, a portion of the blocking layer BX, a portion of the charge trap layer CTL, and a portion of the tunnel isolation layer TX. For instance, a wet etching process may be performed as the etching process for removing the first substrate 1SUB. The etching process for removing the barrier layer BR, the first sacrificial layer 1SC, a portion of the blocking layer BX, a portion of the charge trap layer CTL, and a portion of the tunnel isolation layer TX may be performed using different etchants depending on a layer to be etched. When the first sacrificial layer 1SC and a portion of the blocking layer BX are removed, a portion of the first material layers 1M (41) and a portion of the channel layer CH may be exposed.

Referring to FIG. 4N, an ion implantation process, as indicated by the arrows, may be performed to implant impurities into a portion of the exposed channel layer CH. The ion implantation process may be performed using the N-type impurity or P-type impurity. For instance, the ion implantation process may be performed to implant the N-type impurity or P-type impurity into the channel layer CH. Phosphorus (P) or arsenic (As) may be used as the N-type impurity, and boron (B) may be used as the P-type impurity. When the N-type impurity is implanted, gate induced drain leakage (GIDL) may occur in the channel layer CH of an area where the source select transistors are formed. The step of implanting the P-type impurity may be selectively performed as an option. In an embodiment, when the N-type impurity is implanted, GIDL occurring in the channel layer CH of the area where the source select transistors are formed can be improved. The ion implantation process may be performed so that the impurity may be implanted into the channel layer CH of a source region REs where the source select transistors are located. Because, in an embodiment, the exposed channel layer CH is located in the source region REs of the memory block, the electrical characteristics of the source select transistors can be improved by the ion implantation process performed on a portion of the exposed channel layer CH.

When the channel layer CH is formed of doped polysilicon, the ion implantation process described with reference to FIG. 4N may be omitted.

Referring to FIG. 4O, a source line SL may be formed to cover both the exposed channel layer CH and the first material layer 1M. The source line SL may be formed of a conductive material. For instance, the source line SL may be formed of a doped polysilicon layer. After the doped polysilicon layer is formed, a metal layer may be further formed.

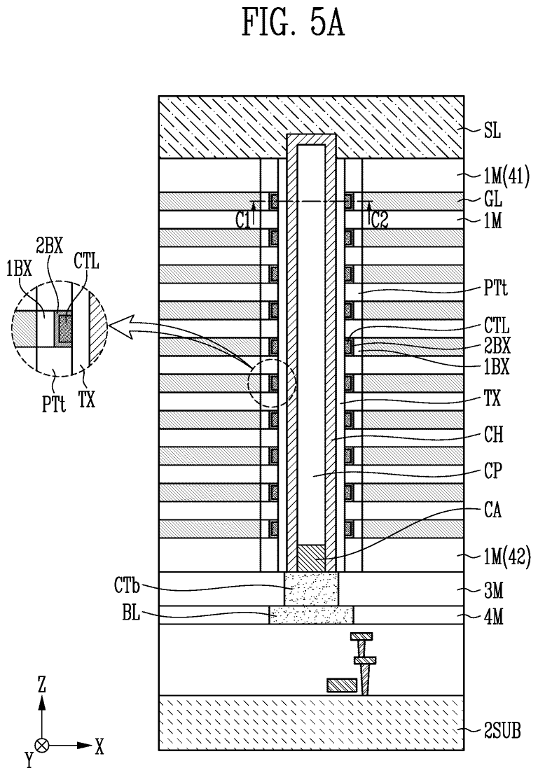

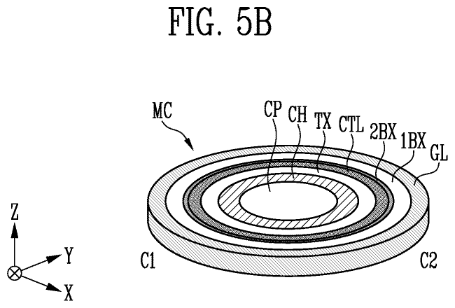

FIGS. 5A and 5B are views illustrating a structure of a memory device according to second embodiments of the present disclosure.

FIG. 5A shows a portion of a memory block included in the memory device, and FIG. 5B shows the structure of a memory cell MC.

Referring to FIGS. 5A and 5B, in the memory device according to various second embodiments, a second blocking layer 2BX is further added to the memory device according to a first embodiment. The blocking layer of a first embodiment becomes the first blocking layer 1BX in a second embodiment. Referring to a C1-C2 plane, the first blocking layer 1BX may contact the gate line GL, and the second blocking layer 2BX may enclose a portion of the charge trap layer CTL. The second blocking layer 2BX may be formed as a high-K layer with a higher dielectric constant (i.e., K, kappa) than the first blocking layer 1BX. The second blocking layer 2BX may be located between the charge trap layer CTL and the first blocking layer 1BX or between the charge trap layer CTL and the protruding pattern PTt. In some embodiments, the second blocking layer 2BX is not formed between the charge trap layer CTL and the tunnel isolation layer TX. Therefore, the charge trap layer CTL may contact the tunnel isolation layer TX.

In the manufacturing method described with reference to FIG. 4D of a first embodiment, the second blocking layer 2BX may be formed along the surfaces of the protrusions PT and the first blocking layers 1BX before forming the charge trap layer CTL. In an embodiment of the manufacturing method described with reference to FIG. 4E, a portion of the second blocking layers 2BX formed on the surfaces of the protrusions PT may be simultaneously removed when removing a portion of the protrusions PT. The words “simultaneous” and “simultaneously” as used herein with respect to processes mean that the processes take place on overlapping intervals of time. For example, if a first process takes place over a first interval of time and a second process takes place simultaneously over a second interval of time, then the first and second intervals at least partially overlap each other such that there exists a time at which the first and second processes are both taking place.

Therefore, the memory cell MC of the memory device according to a second embodiment may include a core pillar CP, a channel layer CH enclosing the core pillar CP, a tunnel isolation layer TX enclosing the channel layer CH, a charge trap layer CTL enclosing the tunnel isolation layer TX, a second blocking layer 2BX enclosing the charge trap layer CTL, and a first blocking layer 1BX enclosing the second blocking layer 2BX. The gate line GL may enclose the first blocking layer 1BX.

When the second blocking layer 2BX is included in the memory cell MC, in an embodiment, a coupling ratio may increase between the charge trap layer CTL and the gate line GL. Hence, during the read operation, in an embodiment, the amount of current flowing through the channel layer CH of the memory cell MC may increase. Further, in an embodiment, retention characteristics in which electrons trapped in the charge trap layer CTL are maintained can be improved.

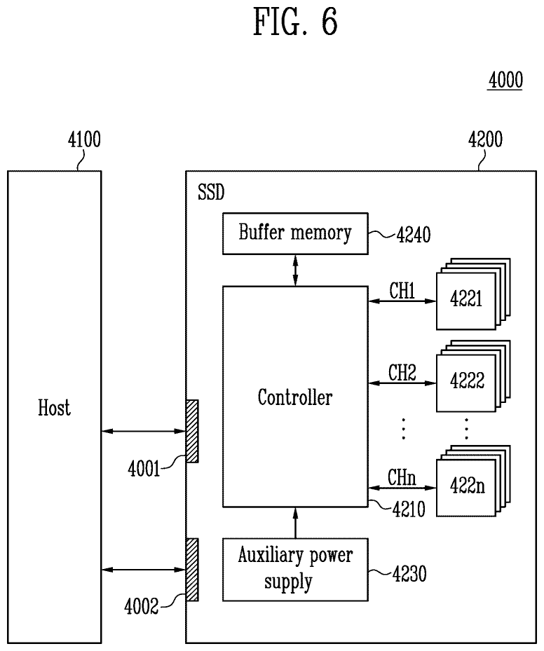

FIG. 6 is a diagram illustrating a solid state drive (SSD) system to which a memory device according to the present disclosure is applied.

Referring to FIG. 6, an SSD system 4000 includes a host 4100 and an SSD 4200. The SSD 4200 may exchange a signal with the host 4100 through a signal connector 4001, and may receive power through a power connector 4002. The SSD 4200 may include a controller 4210, memory devices 4221 to 422n, an auxiliary power supply 4230, and a buffer memory 4240.

According to an embodiment of the present disclosure, each of the memory devices 4221 to 422n may be configured in the same manner as the memory device 100 described above with reference to FIG. 1.

The controller 4210 may control the memory devices 4221 to 422n in response to a signal received from the host 4100. In an embodiment, the signal may include signals based on the interfaces of the host 4100 and the SSD 4200. For example, the signal may be a signal defined by at least one of interfaces such as universal serial bus (USB), multimedia card (MMC), embedded MMC (eMMC), peripheral component interconnection (PCI), PCI-express (PCI-E), advanced technology attachment (ATA), serial-ATA (SATA), parallel-ATA (PATA), small computer system interface (SCSI), enhanced small disk interface (ESDI), integrated drive electronics (IDE), Firewire, universal flash storage (UFS), WiFi, Bluetooth, and nonvolatile memory express (NVMe).

The auxiliary power supply 4230 may be coupled to the host 4100 through the power connector 4002. The auxiliary power supply 4230 may be supplied with a supply voltage from the host 4100, and may be charged with the supply voltage. The auxiliary power supply 4230 may provide the supply voltage to the SSD 4200 when the supply of power from the host 4100 is not abnormally performed. In an embodiment, the auxiliary power supply 4230 may be located inside the SSD 4200 or located outside the SSD 4200. For example, the auxiliary power supply 4230 may be located on a main board, and may also provide auxiliary power to the SSD 4200.

The buffer memory 4240 may be used as a buffer memory of the SSD 4200. For example, the buffer memory 4240 may store data received from the host 4100 or data received from the memory devices 4221 to 422n, or may store metadata (e.g., mapping tables) of the memory devices 4221 to 422n. The buffer memory 4240 may include volatile memories, such as DRAM, SDRAM, DDR SDRAM, and LPDDR SDRAM, or nonvolatile memories, such as FRAM, ReRAM, STT-MRAM, and PRAM.

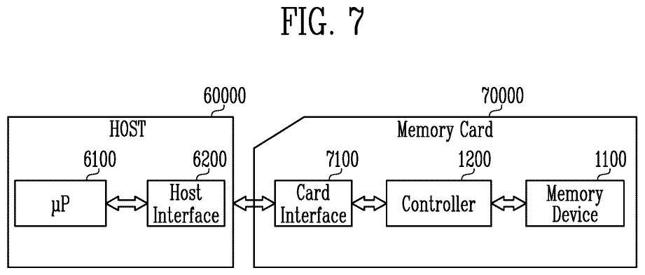

FIG. 7 is a diagram illustrating a memory card system to which a memory device according to the present disclosure is applied.

Referring to FIG. 7, a memory system 70000 may be implemented as a memory card or a smart card. The memory system 70000 may include a memory device 1100, a controller 1200, and a card interface 7100.

The memory device 1100 may be configured in the same manner as the memory device 100 illustrated in FIG. 1.

The controller 1200 may control data exchange between the memory device 1100 and the card interface 7100. In an embodiment, the card interface 7100 may be, but is not limited to, a secure digital (SD) card interface or a multimedia card (MMC) interface.

The card interface 7100 may interface data exchange between a host 60000 and the controller 1200 according to a protocol of the host 60000. In accordance with an embodiment, the card interface 7100 may support a universal serial bus (USB) protocol and an interchip (IC)-USB protocol. Here, the card interface 7100 may refer to hardware capable of supporting the protocol which is used by the host 60000, software installed in the hardware, or a signal transmission method.

When the memory system 70000 is coupled to a host interface 6200 of the host 60000 such as a PC, a tablet PC, a digital camera, a digital audio player, a mobile phone, console video game hardware or a digital set-top box, the host interface 6200 may perform data communication with the memory device 1100 through the card interface 7100 and the controller 1200 under the control of a microprocessor (UP) 6100.

According to an embodiment of the present disclosure, the retention characteristics of a memory device can be improved.

What is claimed is:

1. A memory device, comprising:
gate lines stacked to be spaced apart from each other;
first blocking layers enclosed by the gate lines, the first blocking layers stacked to be spaced apart from each other;
charge trap layers enclosed by the first blocking layers, the charge trap layers stacked to be spaced apart from each other;
protruding patterns located between the first blocking layers and between the charge trap layers;
a tunnel isolation layer enclosed by the charge trap layers and the protruding patterns; and
a channel layer enclosed by the tunnel isolation layer.

2. The memory device according to claim 1, further comprising:
material layers located between the gate lines, the material layers enclosing the protruding patterns.

3. The memory device according to claim 1, wherein the protruding patterns comprise an insulating material.

4. The memory device according to claim 1, wherein a sum of thicknesses comprising a first blocking layer and a charge trap layer located on the same layer among the first blocking layers and the charge trap layers is substantially identical to a thickness of a protruding pattern from among the protruding patterns.

5. The memory device according to claim 1, wherein a sum of thicknesses of a first blocking layer and a charge trap layer located on the same layer among the first blocking layers and the charge trap layers is less than a thickness of a protruding pattern from among the protruding patterns.

6. The memory device according to claim 1, wherein the tunnel isolation layer and the channel layer extend along a direction in which the charge trap layers are stacked.

7. The memory device according to claim 1, further comprising:
an impurity implanted into the channel layer of a drain region where drain select transistors are located and a source region where source select transistors are located.

8. The memory device according to claim 7, wherein the impurity is an N-type impurity.

9. The memory device according to claim 7, wherein the impurity includes a P-type impurity and an N-type impurity.

10. The memory device according to claim 1, further comprising:
second blocking layers enclosing a portion of the charge trap layers.

11. The memory device according to claim 10, wherein the second blocking layers comprising high-K layers, the high-K layers having a higher dielectric constant than the first blocking layers.

12. The memory device according to claim 10, wherein each of the second blocking layers is located between each of the charge trap layers and each of the first blocking layers and between each of the charge trap layers and each of the protruding patterns.

13. The memory device according to claim 10, wherein the charge trap layers contact the tunnel isolation layer.

14. A method of manufacturing a memory device, comprising:
alternately stacking first material layers and sacrificial layers;
forming an opening to expose surfaces of the first material layers and the sacrificial layers;
selectively forming protrusions on the first material layers exposed through the opening;
forming first blocking layers and charge trap layers on the sacrificial layers exposed between the protrusions;
forming protruding patterns by removing a portion of the protrusions that protrude between the charge trap layers;
forming a tunnel isolation layer along surfaces of the protruding patterns and the charge trap layers; and
forming a channel layer along a surface of the tunnel isolation layer.

15. The method according to claim 14, wherein forming the opening is performed by an anisotropic dry etching process.

16. The method according to claim 14, wherein the protrusions are formed of an insulating material.

17. The method according to claim 14, wherein the protrusions are oxidized from surfaces of the first material layers excluding the sacrificial layers.

18. The method according to claim 14, wherein the protrusions are formed to protrude toward a center of the opening.

19. The method according to claim 14, wherein, in forming the first blocking layers and the charge trap layers,
the first blocking layers are formed on surfaces of the sacrificial layers, and
the charge trap layers are formed on surfaces of the first blocking layers.

20. The method according to claim 14, wherein the protruding patterns are portions remaining after removing portions of the protrusions that protrude toward the center of the opening beyond the charge trap layers.

21. The method according to claim 14, further comprising:
implanting a first impurity into the channel layer, after forming the channel layer.

22. The method according to claim 21, wherein an N-type impurity is used as the first impurity.

23. The method according to claim 14, further comprising:
after forming the channel layer,
forming a core pillar and a capping layer in an area enclosed by the channel layer;
implanting a second impurity into an upper area of the capping layer and the channel layer;
removing the sacrificial layers and forming gate lines in areas where the sacrificial layers are removed;
flipping an entire structure including the gate lines and exposing a portion of the channel layer through an upper portion of the flipped entire structure;
implanting a third impurity into the exposed channel layer; and
forming a source line on the upper portion of the entire structure including the channel layer.

24. The method according to claim 23, wherein an N-type impurity is used as the first to third impurities.

25. The method according to claim 23, wherein a P-type impurity and an N-type impurity are used as the first to third impurities.

26. The method according to claim 14, further comprising:
between forming the tunnel isolation layer and forming the channel layer,
forming a second blocking layer along surfaces of the tunnel isolation layer and each of the protruding patterns.

27. The method according to claim 26, wherein the second blocking layer is formed of a high-K layer with a higher dielectric constant than the first blocking layer.
